(19) United States
(12) Patent Application Publication
(10) Pub. No.: US 2026/0068709 A1
(43) Pub. Date: Mar. 5, 2026

(54) MULTI-LAYER ELECTRONIC DEVICE PACKAGE

(71) Applicant: TEXAS INSTRUMENTS INCORPORATED, DALLAS, TX (US)

(72) Inventors: Sylvester ANKAMAH-KUSI, MCKINNEY, TX (US); Shawn O'CONNOR, MCKINNEY, TX (US); Jovenic ESQUEJO, BAGUIO CITY (PH); Blake TRAVIS, RICHARDSON, TX (US); Harshpreet Singh Phull BAKSHI, DALLAS, TX (US); Rajen Manicon MURUGAN, DALLAS, TX (US); Muhammad KHAN, PLANO, TX (US)

(21) Appl. No.: 18/818,573

(22) Filed: Aug. 28, 2024

(51) Int. Cl. H01L 23/498; H01L 21/48; H01L 23/00; H01L 23/31

(52) U.S. Cl. CPC H01L 23/49838

(57) ABSTRACT

An electronic device includes a die, a ground die attach pad, and a power supply die attach pad. Wire bonds connect ground nets from the die to the ground die attach pad. Additional wire bonds connect power supply nets from the die to the power supply die attach pad.

Additional wire bonds connect signal nets from the die to pins on a periphery of the electronic device.

### TECHNICAL FIELD

The present disclosure relates to electronic devices, and more specifically to an electronic device having multiple die attach pads.

### BACKGROUND

Dies in an integrated circuit (IC) package have signal nets and power nets. The IC package is comprised of a larger thermal or ground pad and input/output (I/O) pins around a periphery of the IC package. Each signal net performs a specific function (e.g., enable, reset, etc.). The power nets are comprised of power supply (e.g., VDD) nets and ground (GND) nets. In the IC package, the ground nets are routed to the ground pad. The power supply nets, on the other hand, must be routed to the I/O pins thereby reducing the number of I/O pins for the signal nets, which limits the functionality of the IC package. The VDD power supply pins on the periphery of the IC package require a large amount of current and low resistance and inductance to maintain a stable and constant voltage. Any fluctuation on the VDD voltage will compromise the performance of the IC package. Specifically, high amounts of inductance can cause the VDD voltage to destabilize and induce noise in the signal I/O pins thereby compromising the performance of the IC package.

### SUMMARY

In a described example, an electronic device includes a die, a ground die attach pad, and a power supply die attach pad. Wire bonds connect ground nets from the die to the ground die attach pad, connect power supply nets from the die to the power supply die attach pad, and connect signal nets from the die to pins on a periphery of the electronic device.

In another described example, an electronic device includes a first layer having at least two die attach pads and a second layer having at least two first electrical pads, where the at least two first electrical pads are substantially aligned with the at least two die attach pads. A third layer includes at least two second electrical pads, where the at least two second electrical pads are substantially aligned with the at least two first electrical pads. A die is disposed on the first layer and wire bonds connect power nets from the die to the at least two die attach pads and connect signal nets from the die to pins on a periphery of the electronic device.

In still another described example, a method includes forming a first plated layer in a surface of a substrate and forming a second plated layer in an opposite surface of the substrate, where the first plated layer is electrically connected to the second plated layer via a via layer, wherein inner walls of vias in the via layer are plated. A third plated layer is formed on the second plated layer. Wire bonds provide a connection from a die disposed on the first plated layer to the first plated layer and a mold compound is formed over the die and wire bonds.

### BRIEF DESCRIPTION OF THE DRAWINGS

FIGS. 1A and 1B are top and bottom views of an example electronic device.

FIG. 2 is a top view of a first layer of the example electronic device of FIGS. 1A and 1B.

FIG. 3 is a top view of a second layer of the example electronic device of FIGS. 1A and 1B.

FIG. 4 is a top view of a via layer of the example electronic device of FIGS. 1A and 1B.

FIG. 5 is a top view of a third layer of the example electronic device of FIGS. 1A and 1B.

FIG. 6 is a graph illustrating an affect on inductance on the electronic device of FIGS. 1A and 1B.

FIG. 7 is a block diagram flow chart explaining a fabrication process of the electronic device of FIGS. 1A and 1B.

FIG. 8A illustrates a cross-sectional view of a substrate in the early stages of fabrication.

FIG. 8B illustrates a cross-sectional view of the substrate of FIG. 8A after the formation of vias.

FIG. 8C illustrates a cross-sectional view of the substrate of FIG. 8B after undergoing deposition of a seed layer.

FIG. 8D illustrates a cross-sectional view of the substrate of FIG. 8C after undergoing a first photoresist material layer patterning.

FIG. 8E illustrates a cross-sectional view of the substrate of FIG. 8D after undergoing a first plating process.

FIG. 8F illustrates a cross-sectional view of the substrate of FIG. 8E after undergoing removal of the first photoresist material layer.

FIG. 8G illustrates a cross-sectional view of the substrate of FIG. 8F after undergoing a second photoresist material layer patterning.

FIG. 8H illustrates a cross-sectional view of the substrate of FIG. 8G after undergoing a second plating process.

FIG. 8I illustrates a cross-sectional view of the substrate of FIG. 8H after undergoing removal of the second photoresist material layer.

FIG. 8J illustrates a cross-sectional view of the substrate of FIG. 8I after undergoing a third photoresist material layer patterning.

FIG. 8K illustrates a cross-sectional view of the substrate of FIG. 8J after undergoing a third plating process.

FIG. 8L illustrates a cross-sectional view of the substrate of FIG. 8K after undergoing removal of the third photoresist material layer.

FIG. 8M illustrates a cross-sectional view of the substrate of FIG. 8L after placement of a die on the first layer.

FIG. 8N illustrates a cross-sectional view of the substrate of FIG. 8M after undergoing placement of wire bonds from the die to the first layer.

FIG. 8O illustrates a cross-sectional view of the substrate of FIG. 8N after undergoing a formation of a mold compound.

### DETAILED DESCRIPTION

Dies in an integrated circuit (IC) package have signal nets and power nets. The IC package is comprised of a larger thermal or ground pad (e.g., copper pad) and input/output (I/O) pins (e.g., copper pins) around a periphery of the IC package. Each signal net performs a specific function (e.g., enable, reset, etc.). The power nets are comprised of power supply (e.g., VDD) nets and ground (GND) nets. In the IC package, the ground nets are routed to the ground pad.

The power supply nets, on the other hand, must be routed to the I/O pins thereby reducing the number of I/O pins for the signal nets, which limits the functionality of the IC package. The VDD power supply pins on the periphery of the IC package require a large amount of current and low resistance and inductance to maintain a stable and constant voltage. Any fluctuation on the VDD voltage will compromise the performance of the IC package. Specifically, high amounts of inductance can cause the VDD voltage to destabilize and induce noise in the signal I/O pins thereby compromising the performance of the IC package.

Specifically, as the inductance increases, the VDD power become unstable and thus will fluctuate (e.g., between 2.0 volts and 1.5 volts). This fluctuation in turn generates ringing or noise which interferes with the signal I/O pins thereby compromising the operation of the IC package. The amount of inductance is influenced by the volume of copper in the IC package. As previously mentioned, the ground nets are connected to the large copper ground pad. Thus, the volume of the large copper pad is sufficient to maintain the inductance at low levels. The VDD power supply nets, on the other hand, are connected to the I/O pins. The volume of copper on the I/O pins is not sufficient to maintain the inductance at the required low level. Thus, to generate enough copper volume connected to the VDD power supply nets to maintain the low inductance, a large number of VDD power supply nets must be connected to a large number of I/O pins. Therefore, a large number of I/O pins are dedicated as VDD power supply pins, which limits the number of signal nets that can be connected to the I/O pins thus limiting the functionality of the IC package.

Disclosed herein is an electronic device (e.g., integrated circuit (IC) package that overcomes the aforementioned disadvantages. Specifically, disclosed herein is a multi-layer substrate electronic device that includes multiple die attach pads (DAP). The multiple DAP's allow both the power supply nets and the ground nets from the die to be down-bonded to their respective DAP (i.e., VDD and ground). The configuration of the multiple DAP's frees up I/O pins on the periphery of the IC package to allow more I/O pins to be used for signal nets which increases functionality and/or reduces package size. In addition, the size of the multiple DAP's provides a sufficient volume of copper for both the power nets and the signal nets to maintain a low level of inductance (e.g., approximately 0.4-1.8 nH). It is to be understood that an acceptable low range of inductance will vary based on the type of IC package. The DAP's are provided on multiple layers of the substrate package and the multiple layers are electrically connected to each other through a layer of vias. Depending on the application and the package design, the vias may be cylindrical, hollow vias with plated copper walls or solid copper vias or a combination to the two. An additional bottom layer is provided as a footprint that attaches to an end user's electrical device (e.g., printed circuit board (PCB)).

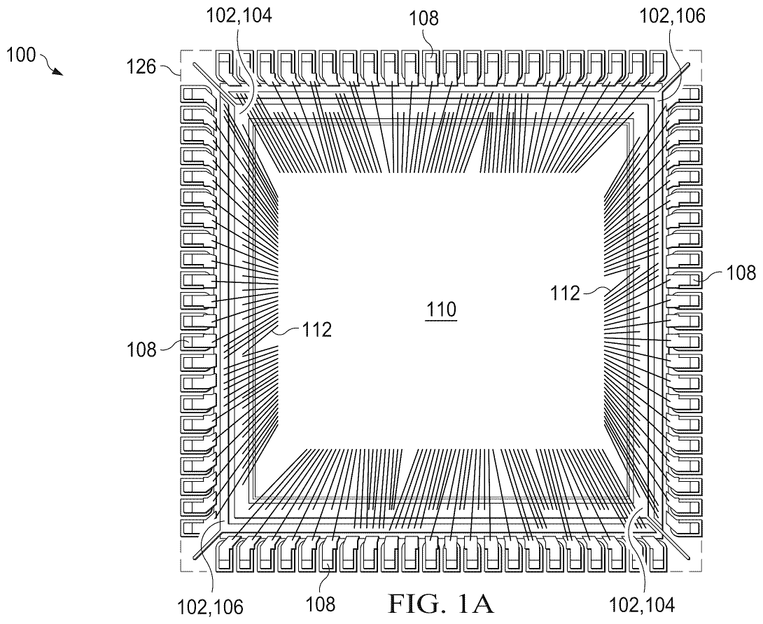

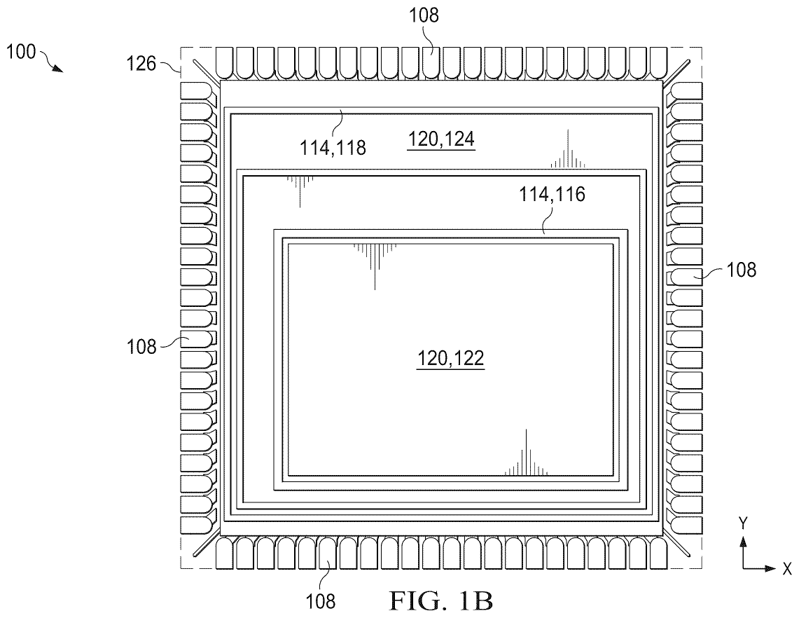

FIGS. 1A and 1B are top and bottom views respectively of a multi-layer substrate electronic device (e.g., integrated circuit (IC)) 100 that includes multiple die attach pads. The die attach pads are comprised of an electrically conductive metal (e.g., copper) of sufficient volume to drive down the inductance in the electronic device 100 and maintain the inductance at a low level (e.g., 0.4-1.8 nH). The electronic device 100 is a substrate type device and can be comprised of any type of a multi-layer substrate integrated circuit (IC) including, but not limited to a land-grid array (LGA), a ball-grid array (BGA) package, etc. Thus, the example electronic device 100 illustrated in FIGS. 1A and 1B is for illustrative purposes only and is not intended to limit the scope of the invention.

The electronic device 100 is a multi-layer, multi DAP substrate device that includes a first (top) layer 102 comprised of a ground die attach pad (GND DAP) 104 and a power supply die attach pad (VDD DAP) 106 where the GND DAP 104 and the VDD DAP 106 are on a first plane. The VDD DAP 106 comprises two L-shaped bars that are disposed near a periphery of the first layer 102. Thus, the VDD L-shaped bars 106 surround the GND DAP 104. Pins 108 are disposed around the periphery of the first layer 102 outside of the VDD L-shaped bars 106. A die 110 is disposed on the first layer. Wire bonds 112 provide connections from the die 110 to the GND DAP 104, to the VDD DAP 106, and to the pins 108. Specifically, some of the wire bonds 112 electrically connect ground nets from the die 110 to the GND DAP 104. Other wire bonds 112 electrically connect power supply nets from the die 110 to the VDD DAP 106. Finally, the remaining wire bonds 112 electrically connect signal nets from the die 110 to the pins 108. As mentioned above, the presence of the VDD DAP 106 allows the power supply nets from the die 110 to connect to the VDD DAP 106 and not to the pins 108. This allows more signal nets from the die 110 to connect to the pins 108. Since different signal nets have different functions (e.g., enable, reset, etc.), the functionality of the electronic device 100 increases.

Referring to FIG. 1B, the electronic device 100 further includes a second (intermediate) layer 114 comprising a first ground pad 116 and a first power supply pad 118 where the first ground pad 116 and the first power pad 118 are on a second plane. A via layer not shown in FIGS. 1A and 1B electrically connects the first 102 and the second layers 114. Specifically, the via layer includes vias that electrically connect the GND DAP 104 of the first layer 102 to the first ground pad 116 of the second layer 114 and vias that electrically connect the VDD DAP 106 of the first layer 102 to the first power supply pad 118 of the second layer 114. As will be explained further below, the via layer further includes vias on a periphery of the via layer that electrically connect the pins 108 from the first layer to pins of the second layer 114.

Still referring to FIG. 1B, the electronic device 100 further includes a third (bottom) layer 120 comprised of a second ground pad 122 and a second power supply pad 124 where the second ground pad 122 and the second power pad 124 are on a third plane. As illustrated in FIG. 1B, the first ground pad 116 and the first power supply pad 118 have x-y dimensions that are larger than x-y dimensions of the second ground pad 122 and the second power supply pad 124 respectively. The third layer 120 attaches to an electrical device (e.g., printed circuit board (PCB)) via the pins 108.

Referring back to FIG. 1A, a mold compound 126 is formed over the die 110 and the wire bonds 112. Since the electronic device 100 is a substrate type package, the layers described above are disposed in a substrate (e.g., dielectric). Thus, the mold compound 126 is not formed over the multiple layers and the substrate.

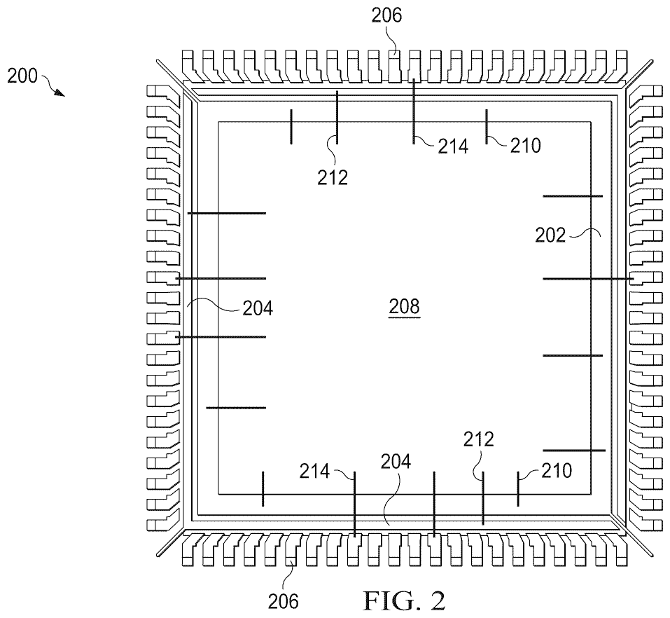

FIGS. 2-5 are top view illustrations of an example first (top) layer 200, an example second (intermediate) layer 300, an example via layer 400, and an example third (bottom) layer 500. The example first, second, and third layers 200, 300, 500 illustrated in FIGS. 2-5 are similar to the first, second, and third layers 102, 114, 120 illustrated in FIGS. 1A and 1B. Thus, reference is to be made to the examples of FIGS. 1A and 1B in the following description of the examples in FIGS. 2-5.

Referring to FIG. 2, the first layer 200 includes power die attach pads (DAP) comprising a ground (GND) DAP 202 and power supply (VDD) DAP's 204 where the GND DAP 202 and the VDD DAP's 204 are on a same plane (first plane). The VDD DAP's are comprised of bars that surround the GND DAP 202 near an outer periphery of the first layer 200. Pins (leads) 206 are disposed around the outer periphery of the first layer 200. Wire bonds provide a connection from power and signal nets on a die 208 disposed on the first layer 200 to the GND DAP 202, the VDD DAP 204, and the pins 206. Specifically, a first set of wire bonds 210 provide a connection between the ground nets on the die 208 to the GND DAP 202. A second set of wire bonds 212 provide a connection between the power nets on the die 208 to the VDD DAP's 204. Finally, a third set of wire bonds 214 provide a connection between the signal nets on the die 208 to the pins 206. In the example illustrated in FIG. 2, only a small sample of wire bonds are illustrated for illustration and simplicity.

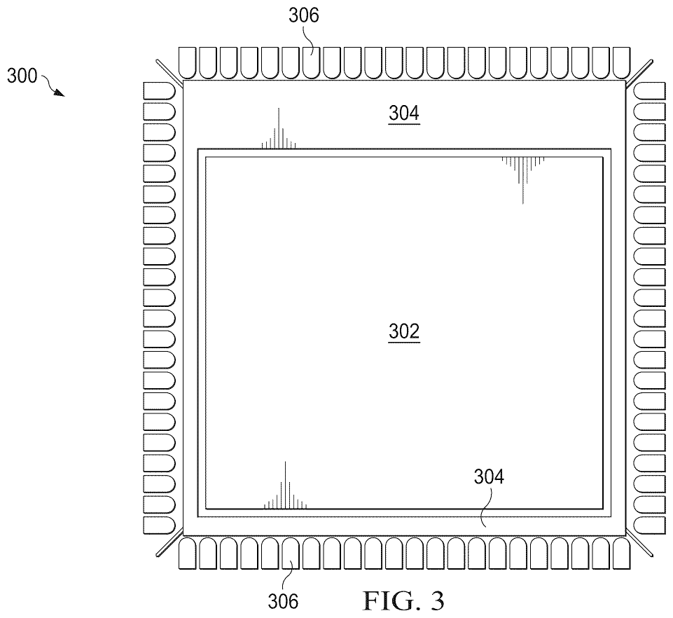

Referring to FIG. 3, the second layer 300 is similar to the first layer 200. The second layer 300 includes a first ground pad 302 and a first power supply pad 304 where the first ground pad 302 and the first power supply pad 304 are on a same plane (second plane). The first power supply pad 304 extends around the first ground pad 302 near a periphery of the second layer 300. Pins (leads) 306 are dispose around the periphery of the second layer and are aligned with the pins 206 on the first layer 200 when the first and second layers 200, 300 are fabricated.

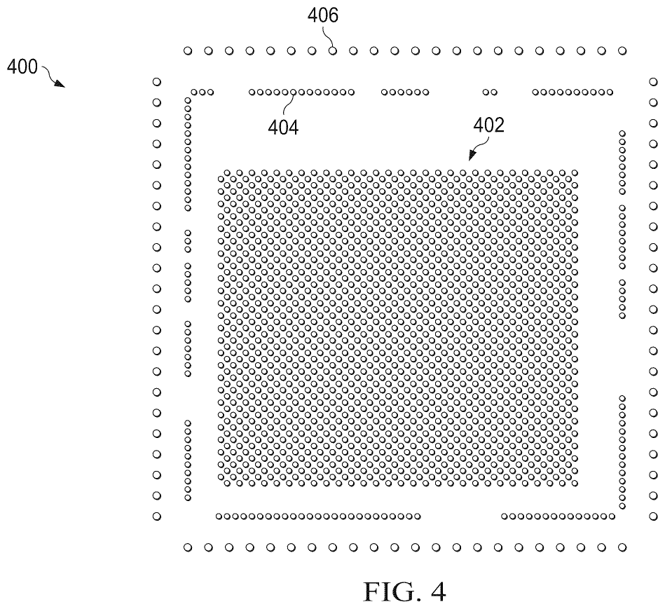

Referring to FIG. 4, the via layer 400 is comprised of vias that provide an electrical connection between the first and second layers 200, 300. Specifically, the via layer 400 includes a first set of vias 402 that provide an electrical connection between the GND DAP 202 of the first layer 200 to the first ground pad 302 of the second layer 300. The via layer 400 further includes a second set of vias 404 that provide an electrical connection between the VDD DAP 204 of the first layer 200 and the first power supply pad 304 of the second layer 300. Finally, the via layer 400 includes a third set of vias 406 that provide an electrical connection between the pins 206 of the first layer 200 and the pins 306 of the second layer 300.

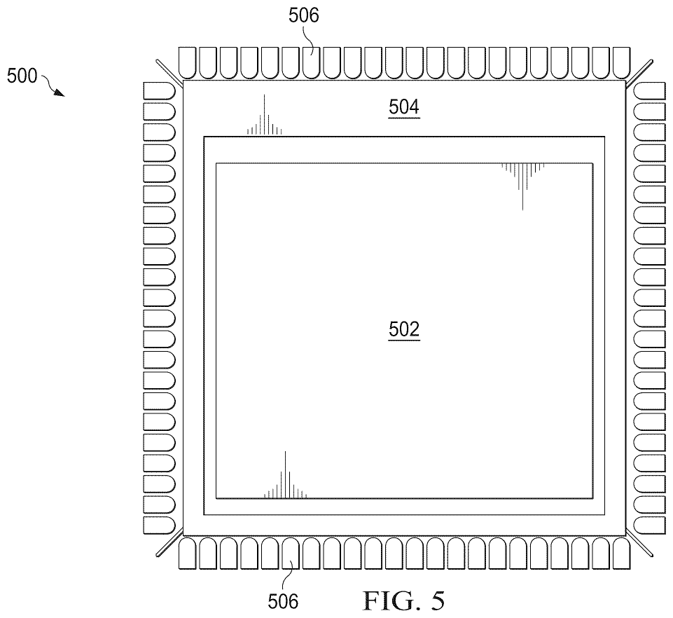

Referring to FIG. 5, the third or bottom layer 500 connects via electroplating to the second layer 300 and has a configuration is similar to the second layer 300. The third layer 500 includes a second ground pad 502 and a second power supply pad 504 where the second ground pad 502 and the second power supply pad 504 are on a same plane (third plane). The second power supply pad 504 extends around the second ground pad 502 near a periphery of the third layer 500. The third layer 500 further includes contacts 506 that are electroplated on a bottom portion of the pins 306 of the second layer 300. During use, the contacts 506 connect to an electrical device (e.g., PCB).

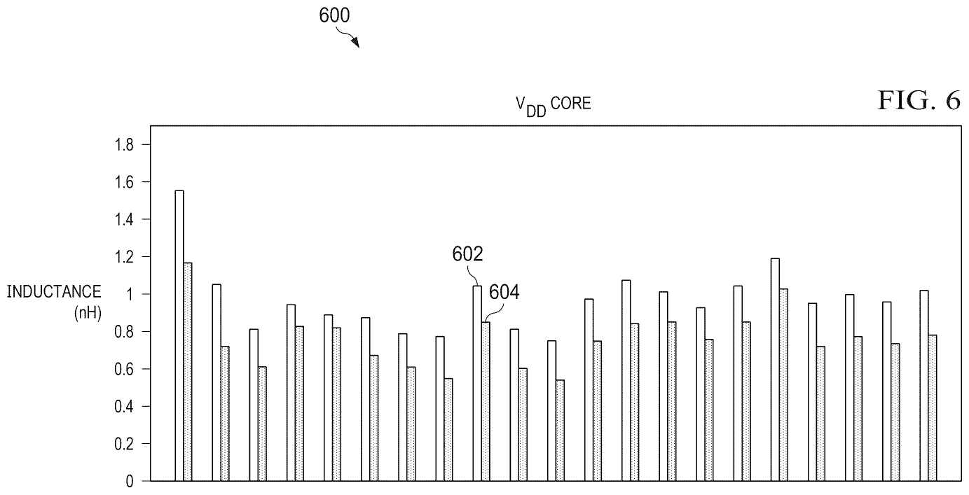

FIG. 6 is a graph 600 illustrating an effect on inductance by implementation of the VDD DAP 106. The graph 600 is a comparison of inductance between a standard QFN package and the electronic device 100 that includes the VDD DAP 106. The bars 602 on the left represent the inductance in the QFN package and the bars 604 on the right represent the inductance in the electronic device 100. In addition, VDD CORE are the main power supply nets (VDD) of the die 110 that are connected to the VDD DAP 106. As illustrated in the graph 600, there is significant improvement in the inductance in the electronic device 100 as compared to the QFN package. Furthermore, additional tests relating to high speed performance of the signal nets and thermal impact resulted in comparable results between the electronic device and the QFN package. Thus, implementation of a separate DAP for power supply (VDD) nets does not have any negative effect on the operation or performance of electronic device 100. Although, the graph illustrates only VDD CORE power supply nets, other power supply nets (e.g., VDD XXX) can be wire bonded to other VDD DAP's. Thus, theoretically, there can be a number of separate VDD DAP's to accommodate all the VDD power supply nets on the die 110.

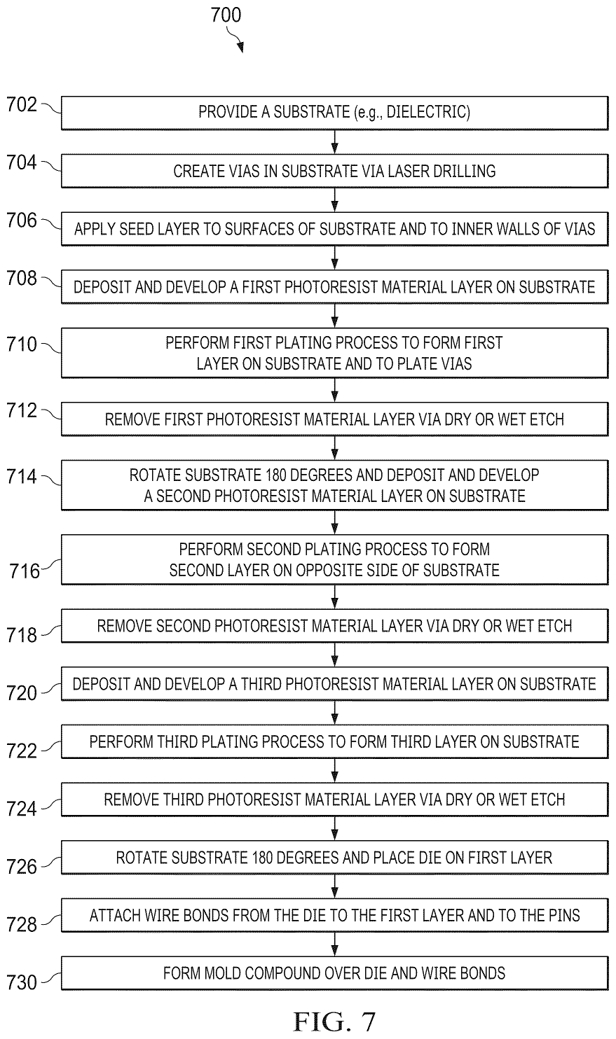

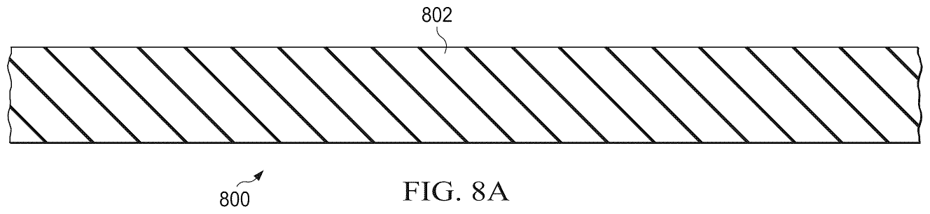

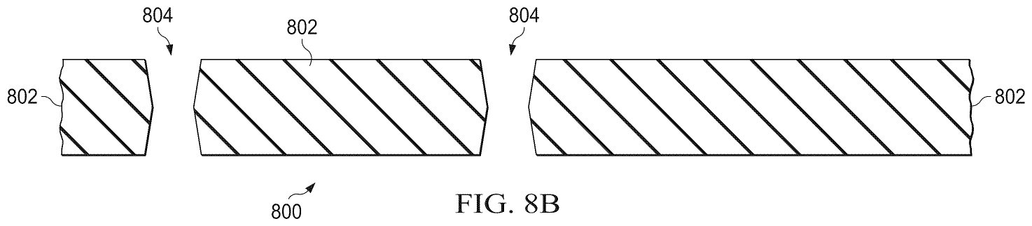

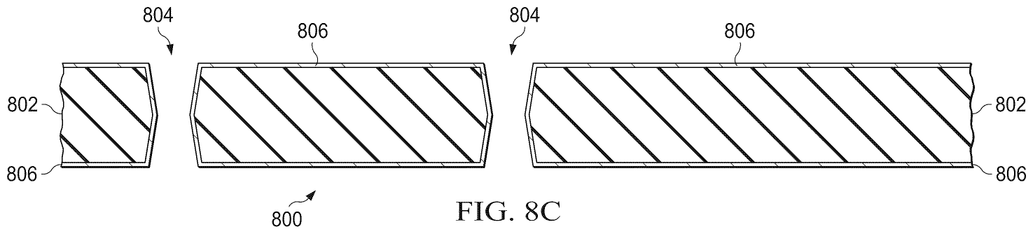

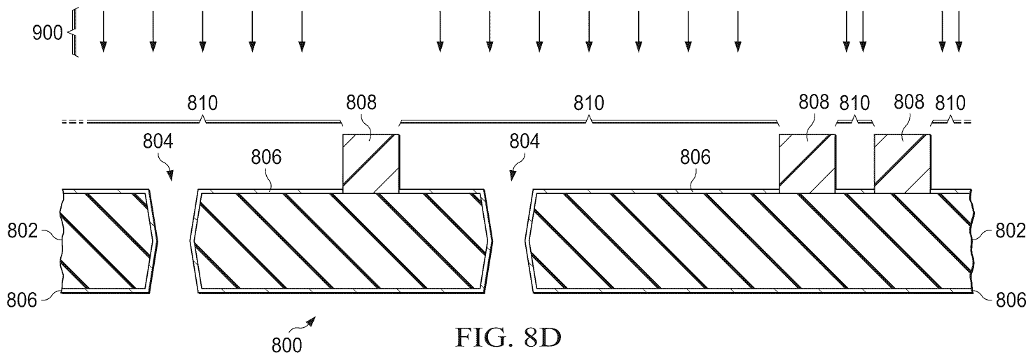

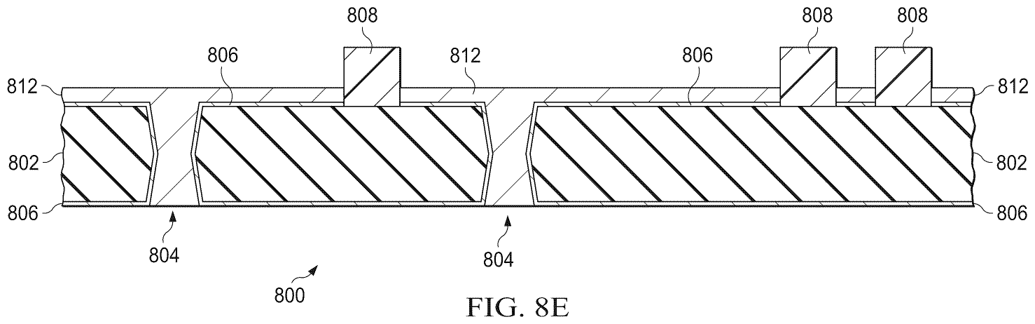

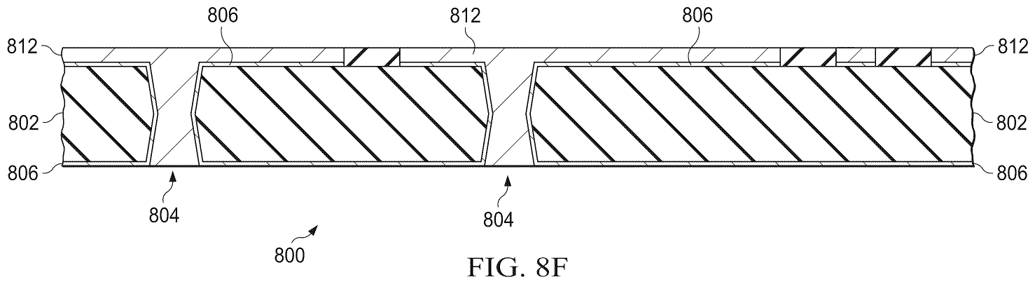

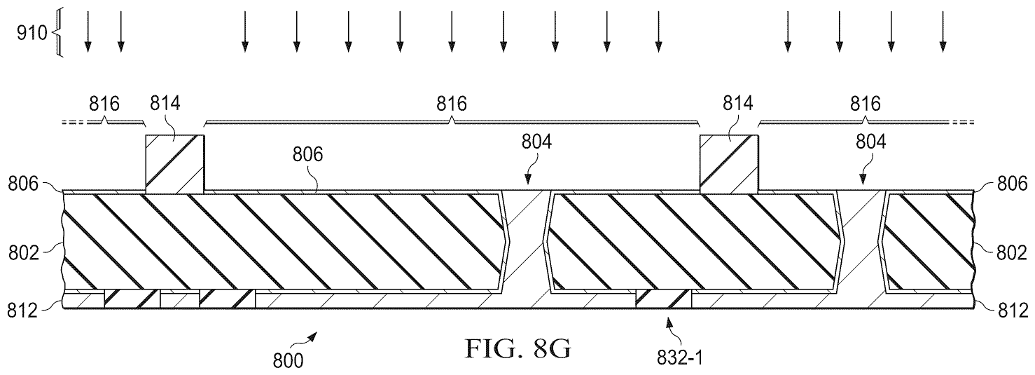

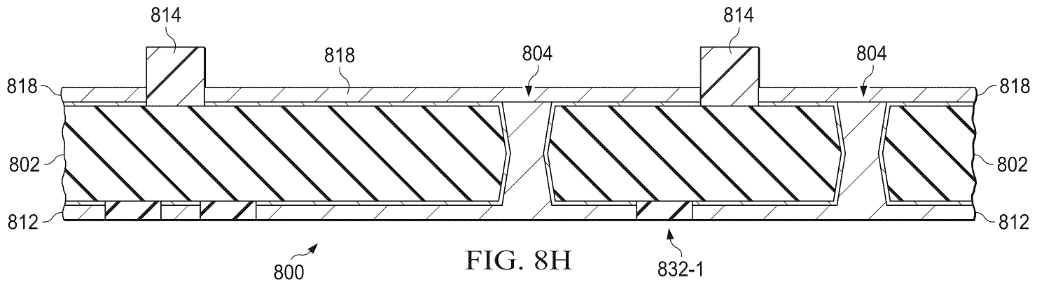

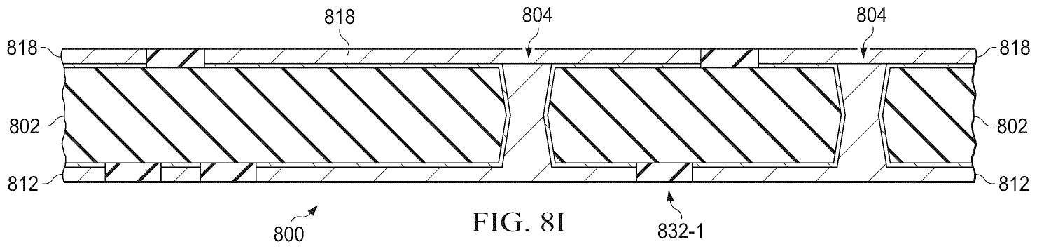

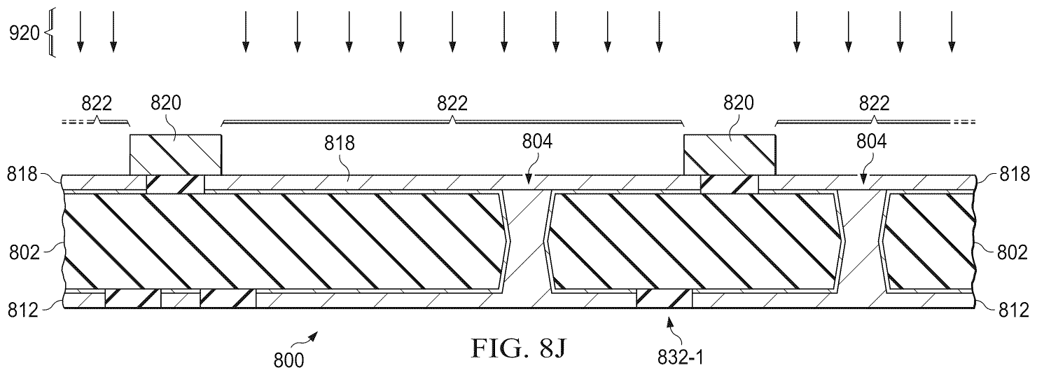

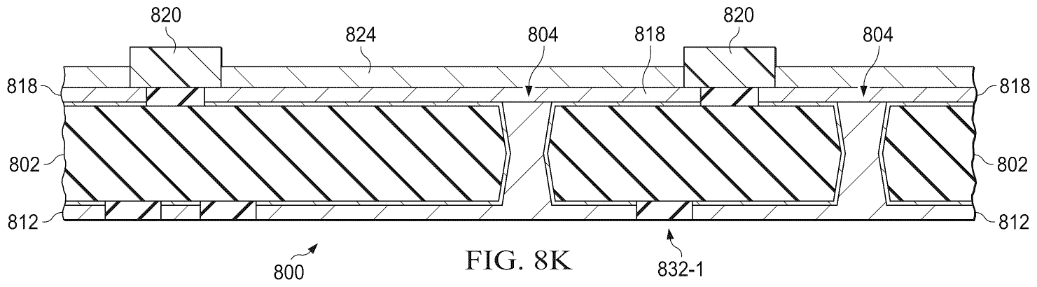

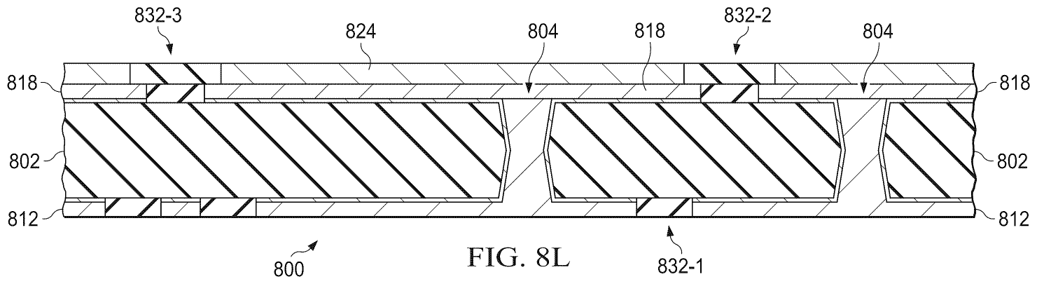

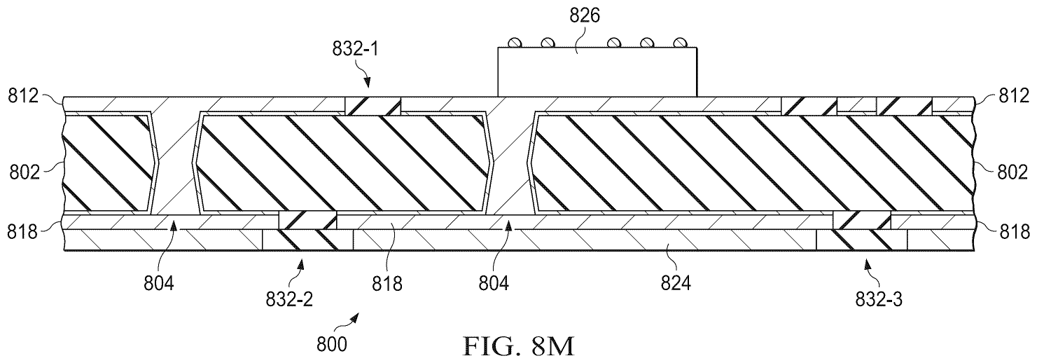

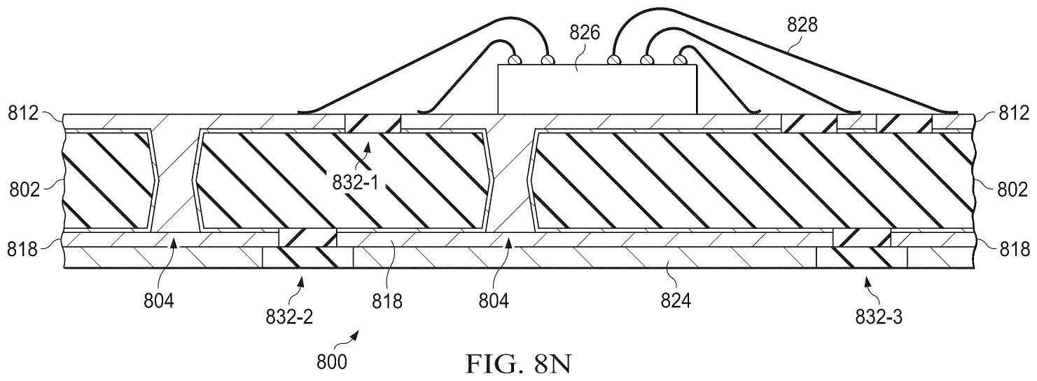

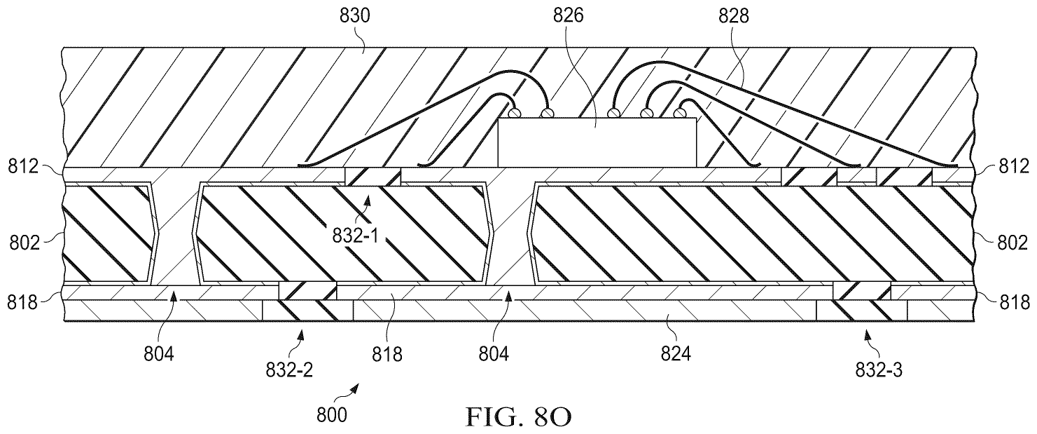

FIG. 7 is a block diagram flow chart explaining a fabrication process 700 and FIGS. 8A-8O illustrate a fabrication process 800 associated with the formation of the electronic device 100 illustrated in FIGS. 1A and 1B. Though depicted sequentially as a matter of convenience, at least some of the actions shown can be performed in a different order and/or performed in parallel. Alternatively, some implementations may perform only some of the actions shown. Still further, although the example illustrated in FIGS. 7 and 8A-8O is an example method illustrating the example configuration of FIGS. 1A and 1B, other methods and configurations are possible. It is understood that although the method illustrated in FIGS. 7 and 8A-8O depicts the fabrication process of a single electronic device, the process applies to an array of electronic devices. Thus, after fabrication of the array of electronic devices the array is singulated to separate each electronic device 100 from the array.

Referring to FIG. 7 and to FIGS. 8A-8O, the fabrication process 800 of the electronic device 100 illustrated in FIGS. 1A and 1B begins at 702 where a substrate (e.g., dielectric) 802 is provided. At 704, vias 804 are created in the substrate 802 via laser drilling resulting in the configuration od FIG. 8B. As explained above, the vias 804 are comprised of a first set, a second set and a third set of vias. For simplicity, however, only two vias are illustrated. Thus, the example in FIGS. 8A-8O are for illustrative purposes only and are not intended to limit the scope of the invention. At 706, a seed layer (e.g., copper seed layer) 806 is applied via electro-less plating to the surfaces of the substrate 802 and to the inner walls of the vias 804 resulting in the configuration od FIG. 8C.

At 708, a first photoresist material layer 808 overlies the substrate 802 and is patterned and developed to expose openings 810 in the first photoresist material layer 808 over the substrate 802, resulting in the configuration of FIG. 8D. The first photoresist material layer 808 can have a thickness that varies in correspondence with the wavelength of radiation used to pattern the first photoresist material layer 808. The first photoresist material layer 808 may be formed over the substrate 802 via spin-coating or spin casting deposition techniques, selectively irradiated (e.g., via deep ultraviolet (DUV) irradiation) and developed to form the openings 810.

At 710, the configuration in FIG. 8D undergoes a first plating (electroplating) process 900 to plate a first layer (e.g., copper) 812 in the openings 810 of the first photoresist material layer 808 on the seed layer 806 resulting in the configuration of FIG. 8E. The first layer 812 is plated into a surface of the substrate 802 such that a surface of the first layer 812 is substantially flush with a surface of the substrate 802. As described above, the first layer 812 is comprised of a GND DAP and a VDD DAP. Simultaneously, the inner walls of the vias 804 are plated with the same material as the first layer 812. As mentioned above, the inner walls of the vias 804 may be plated or the vias 804 may be filled with the plating material to form solid vias. At 712, the first photoresist material layer 808 is removed via a dry or wet etch process resulting in the configuration of FIG. 8F.

At 714, the configuration in FIG. 8F is rotated 180° and a second photoresist material layer 814 overlies the substrate 802 and is patterned and developed to expose openings 816 in the second photoresist material layer 814 over the substrate 802, resulting in the configuration of FIG. 8G. The second photoresist material layer 814 can have a thickness that varies in correspondence with the wavelength of radiation used to pattern the second photoresist material layer 814. The second photoresist material layer 814 may be formed over the substrate 802 via spin-coating or spin casting deposition techniques, selectively irradiated (e.g., via deep ultraviolet (DUV) irradiation) and developed to form the openings 816.

At 716, the configuration in FIG. 8G undergoes a second plating (electroplating) process 910 to plate a second layer (e.g., copper) 818 in the openings 816 of the second photoresist material layer 814 and on the seed layer 806 disposed in an opposite surface the substrate 802 resulting in the configuration of FIG. 8H. As described above, the second layer 818 is comprised of a ground pad and a power supply pad. At 718, the second photoresist material layer 814 is removed via a dry or wet etch process resulting in the configuration of FIG. 8I.

At 720, a third photoresist material layer 820 overlies the substrate 802 and is patterned and developed to expose openings 822 in the third photoresist material layer 820 over the substrate 802, resulting in the configuration of FIG. 8J. The third photoresist material layer 820 can have a thickness that varies in correspondence with the wavelength of radiation used to pattern the third photoresist material layer 820. The third photoresist material layer 820 may be formed over the substrate 802 via spin-coating or spin casting deposition techniques, selectively irradiated (e.g., via deep ultraviolet (DUV) irradiation) and developed to form the openings 822.

At 722, the configuration in FIG. 8J undergoes a third plating (electroplating) process 920 to plate a third layer (e.g., copper) 824 in the openings 822 of the third photoresist material layer 820 and on the second layer 818 resulting in the configuration of FIG. 8K. The third layer 824 is plated on the second layer 818 such that a surface of the third layer 824 is substantially flush with the opposite surface of the substrate 802. As described above, the third layer 824 is comprised of a second ground pad and a second power supply pad. At 724, the third photoresist material layer 820 is removed via a dry or wet etch process resulting in the configuration of FIG. 8L.

At 726, the configuration in FIG. 8L is rotated 180° and a die 826 is placed on the first layer 812 resulting in the configuration of FIG. 8M. At 728, wire bonds 828 are attached from the die 826 to the first layer and to pins resulting in the configuration of FIG. 8N. Specifically, as described above, first and second sets of wire bonds are attached from ground and power nets on the die 826 to the GND DAP and the VDD DAP respectively. A third set of wire bonds are connected from signal nets on the die 826 to the pins. At 730, a mold compound 830 is formed over the die 826 and wire bonds 828 resulting in the configuration of FIG. 8O.

As illustrated in FIG. 8O, the first, second and third layers 812, 818, 824 include gaps or spaces 832. Specifically, the first layer includes one or more first gaps 832-1 that physically separate the GND DAP from the VDD DAP. The second layer 818 includes one or more second gaps 832-2 gaps that physically separate the first ground pad from the first power supply pad.

Finally, the third layer 824 includes one or more third gaps 832-3 that physically separate the second ground pad from the second power supply pad.

Described above are examples of the subject disclosure. It is, of course, not possible to describe every conceivable combination of components or methodologies for purposes of describing the subject disclosure, but one of ordinary skill in the art may recognize that many further combinations and permutations of the subject disclosure are possible. Accordingly, the subject disclosure is intended to embrace all such alterations, modifications and variations that fall within the spirit and scope of the appended claims. In addition, where the disclosure or claims recite “a,” “an,” “a first,” or “another” element, or the equivalent thereof, it should be interpreted to include one or more than one such element, neither requiring nor excluding two or more such elements. Furthermore, to the extent that the term “includes” is used in either the detailed description or the claims, such term is intended to be inclusive in a manner similar to the term “comprising” as “comprising” is interpreted when employed as a transitional word in a claim. Finally, the term “based on” is interpreted to mean based at least in part.

What is claimed is:

1. An electronic device comprising:
a die;
a ground die attach pad;
a power supply die attach pad; and
wire bonds connecting ground nets from the die to the ground die attach pad, connecting power supply nets from the die to the power supply die attach pad, and connecting signal nets from the die to pins on a periphery of the electronic device.

2. The electronic device of claim 1, wherein the ground die attach pad and the power supply die attach pad are on a first plane in a first layer.

3. The electronic device of claim 2, wherein the power supply die attach pad comprises L-shaped bars that extend around a periphery of the first layer and substantially surround the ground die attach pad.

4. The electronic device of claim 2 further comprising a second layer comprising a first ground pad and a first power supply pad, wherein the first ground pad and the first power supply pad are on a second plane.

5. The electronic device of claim 4 further comprising a via layer disposed between the first layer and the second layer, the via layer including vias that electrically connect the ground die attach pad to the first ground pad and vias that electrically connect the power supply die attach pad to the first power supply pad.

6. The electronic device of claim 5 further comprising second ground pad disposed on a bottom of the first ground pad and a second power supply pad disposed on the first power supply pad, wherein the second ground pad and the second power supply pad are on a third plane.

7. The electronic device of claim 6, wherein the first ground pad and the first power supply pad have x-y dimensions that are larger than x-y dimensions of the second ground pad and the second power supply pad respectively.

8. An electronic device comprising:
a first layer having at least two die attach pads;
a second layer having at least two first electrical pads, the at least two first electrical pads substantially aligned with the at least two die attach pads;
a third layer having at least two second electrical pads, the at least two second electrical pads substantially aligned with the at least two first electrical pads;
a die disposed on the first layer; and
wire bonds connecting power nets from the die to the at least two die attach pads and connecting signal nets from the die to pins on a periphery of the electronic device.

9. The electronic device of claim 8 further comprising a via layer having vias connecting the at least two die attach pads of the first layer with the at least two first electrical pads of the second layer.

10. The electronic device of claim 9, wherein the at least two die attach pads comprises a ground die attach pad and a power supply die attach pad, wherein the ground die attach pad and the power die attach pad are on a first plane.

11. The electronic device of claim 10, where the at least two first electrical pads comprises a first ground pad substantially aligned with the ground die attach pad and a first power supply pad substantially aligned with the power supply die attach pad, wherein the first ground pad and the first power supply pad are on a second plane.

12. The electronic device of claim 11, where the at least two second electrical pads comprises a second ground pad substantially aligned with the first ground pad and a second power supply pad substantially aligned with the first power supply pad, wherein the second ground pad and the second power supply pad are on a third plane.

13. The electronic device of claim 12, wherein the ground die attach pad and the power supply die attach pad are physically separated by a first gap, wherein the first ground pad and the first power supply pad are physically separated by a second gap, and wherein the second ground pad and the second power supply pad are physically separated by a third gap.

14. The electronic device of claim 10, wherein the power supply die attach pad comprises L-shaped bars that extend around a periphery of the first layer and substantially surround the ground die attach pad.

15. The electronic device of claim 10, wherein the wire bonds comprise a first set of wire bonds connecting ground nets from the die to the ground die attach pad, a second set of wire bonds connecting power supply nets from the die to the power supply die attach pad, and a third set of wire bonds connecting the signal nets from the die to the pins.

16. A method comprising:
forming a first plated layer in a surface of a substrate;
forming a second plated layer in an opposite surface of the substrate, the first plated layer electrically connected to the second plated layer via a via layer, wherein inner walls of vias in the via layer are plated;
forming a third plated layer on the second plated layer;
connecting wire bonds from a die disposed on the first plated layer to the first plated layer; and
forming a mold compound over the die and wire bonds.

17. The method of claim 16, wherein forming the first plated layer includes forming a ground die attach pad via electroplating and forming a power supply die attach pad via electroplating, wherein the ground die attach pad and the power supply die attach pad are on a first plane and physically separated by a first gap.

18. The method of claim 17, wherein forming a second plated layer includes forming a first ground pad and a first power supply pad via electroplating, wherein the first ground pad and the first power supply pad are on a second plane and physically separated by a second gap.

19. The method of claim 18, wherein forming a third plated layer includes forming a second ground pad and a second power supply pad via electroplating, wherein the second ground pad and the second power supply pad are on a third plane and physically separated by a third gap.

20. The method of claim 17, wherein connecting wire bonds from a die disposed on the first plated layer to the first plated layer includes connecting a first set of wire bonds from ground nets on the die to the ground die attach pad, connecting a second set of wire bonds from power supply nets on the die to the power supply die attach pad, and connecting a third set of wire bonds from signal nets on the die to pins on a periphery of the substrate.
